(19) United States
(12) Patent Application Publication
(10) Pub. No.: US 2006/0032447 A1
(43) Pub. Date: Feb. 16, 2006

(54) Processing chamber with wave reflector

(75) Inventors: Ping-Yin Liu, Yonghe City (TW); Ming-Fong Chen, Hsinchu City (TW); Hung-Yin Tsai, Taipei City (TW)

Correspondence Address: BRUCE H. TROXELL, 5205 LEESBURG PIKE, SUITE 1404, FALLS CHURCH, VA, 22041, US

(73) Assignee: Industrial Technology Research Institute

(21) Appl. No.: 11/074,632

(22) Filed: Mar. 9, 2005

(30) Foreign Application Priority Data
Aug. 11, 2004 (TW) 93123995

(51) Int. Cl. C23C 16/00

(52) U.S. Cl. 118/725

(57) ABSTRACT

The processing chamber comprises an energy wave source and a curved spherical surface, wherein the curved spherical surface of the chamber is composed of at least a Fresnel reflector for reflecting the energy wave discharged from the energy wave source and projecting the same onto a platform as the energy wave source is operating in coordination with the curved spherical surface. In addition, the energy wave source can be a microwave source or a light source. It is noted that the curved spherical surface can be a Fresnel reflector, a wave spherical surface with a portion thereof being replaced by a Fresnel reflector, a curved spherical surface with a portion therof being replaced by at least two Fresnel reflectors, and a surface entirely formed of a plurality of Fresnel reflectors. The processing chamber disclosed in the present invention significantly increases energy density, area, and energy uniformity of the projection region so as to diminish required space of equipment and costs of equipment and manufacture.

### FIELD OF THE INVENTION

The present invention relates to a wave reflector, being an approach to adjust the energy density, size and uniformity of a predetermined area, and more particularly, to a processing chamber with wave reflector capable of enabling energy wave to be distributed uniformly.

### BACKGROUND OF THE INVENTION

With rapid progress of chemical vapor deposition (CVD) and excellent physical and chemical properties of diamond, the diamond film can be developed on a specific substrate, for example, a surface acoustic wave device, a diamond transistor, etc. The diamond film is widely applied to cutting tools and optoelectronic communication devices at present. However, the development of the diamond film requires stable and uniform energy to allow the gas precursor to perform decomposition reaction, recomposition reaction, etc. Accordingly, the stability of the applied energy significantly affects deposition quality, uniformity, and deposition speed of the diamond film. For the diamond film-plating machine, energy is supplied by means of Hot filament, microwave or Electron Cyclotron Resonance (ECR), Arc, etc. Moreover, regardless of the type of the CVD method, which is applied for depositing a diamond film on a substrate, energy uniformity becomes more important when the substrate dimension is increased. If the microwave is adopted as the energy wave source, non-uniform energy will affect the shape of plasma ball formed during a deposition process so that partial region of the diamond film is formed non-uniformly. Moreover, the drawback such as non-uniform thickness also affects the processing and application of the diamond film.

As shown in FIG. 1A, a conventional film-plating machine 80 for developing a diamond film on a substrate is shown. This machine consists of a chamber 81 having a cross section of parabolic curve and an energy wave source 82 disposed at a focal point of the parabolic curve of the chamber 81 for supplying energy wave thereto. Accordingly, the energy wave can be projected uniformly on an underneath substrate by means of the parabolic curve of the chamber 81. However, with increase in substrate dimension, the chamber's volume is such increased that the size of the film-plating machine 80 is unduly enlarged and the drawbacks such as increasing manufacture difficulty and manufacture cost are thus caused or any source with energy.

Furthermore, FIG. 1B shows another conventional film-plating machine 80a for developing a diamond film on a substrate. This machine consists of an elliptic chamber 81a and an energy wave source 82a disposed at one of the two focal points of the elliptic chamber 81a for supplying energy wave thereto. Accordingly, the energy wave discharging from the energy wave source is converged and projected onto an underneath substrate disposed at another focal point of the chamber 82a so as to supply high energy. However, since the energy wave source 82a is disposed on a focal point of the elliptic chamber 81a such that the energy wave discharged from the energy wave source 82a is focused on a specific area of the substrate as the size of the substrate increase, the energy wave of the energy wave source 82a that projects to the substrate is non-uniform. Therefore, the drawback of forming a plated film with poor quality on the substrate is thus caused. In order to overcome the above-mentioned drawbacks, the present invention discloses a reflector and a chamber device utilizing the reflector for solving these problems efficiently.

### SUMMARY OF THE INVENTION

The primary object of the invention is to provide a reflector, as well as a processing chamber utilizing the reflector for supplying uniform energy.

Another object of the present invention is to provide a reflector, as well as a processing chamber utilizing the reflector for increasing projection area of an energy wave source.

Still another object of the present invention is to provide a processing chamber with modularized reflectors capable of flexibly changing/adjusting the number of the reflectors installed in the chamber.

In order to accomplish the above-mentioned objects, a process chamber with reflector is provided according to a preferred embodiment of the invention, the processing chamber comprising an energy wave source and a curved spherical surface, wherein the curved spherical surface of the chamber is composed of at least a Fresnel reflector for reflecting the energy wave discharged from the energy wave source and projecting the same onto a platform as the energy wave source is operating in coordination with the curved spherical surface. In addition, the energy wave source can be a microwave source or a light source.

It is noted that the curved spherical surface can be a Fresnel reflector, a waved spherical surface with a portion thereof being replaced by a Fresnel reflector, a curved spherical surface with a portion thereof being replaced by at least two Fresnel reflectors, and a surface entirely formed of a plurality of Fresnel reflectors.

In another preferred embodiment of the present invention, a processing chamber with reflectors comprises at least an energy wave source and at least a curved surface, each operating with respect to a corresponding energy wave source, wherein the energy wave discharged from each energy wave source is reflected by the corresponding curved surface onto a platform. In addition, the energy wave source can be a microwave source or a light source.

Similarly, each curved surface can be a Fresnel reflector, a waved spherical surface with a portion thereof being replaced by a Fresnel reflector, a curved spherical surface with a portion thereof being replaced by at least two Fresnel reflectors, and a surface entirely formed of a plurality of Fresnel reflectors.

Other objects, advantages and novel features of the present invention will be drawn from the following detailed embodiments of the present invention with attached drawings.

### BRIEF DESCRIPTION OF THE DRAWINGS

FIG. 1A is a conventional film-plating machine.

FIG. 1B is another conventional film-plating machine.

FIG. 2A is a preferred embodiment of a curved spherical surface of the present invention.

FIG. 2B is a reflector of a curved-surface structure of prior arts.

FIG. 2C is a schematic view showing a reflector of the present invention.

FIG. 3 is a first preferred embodiment of a processing chamber of the present invention.

FIG. 4 is a second preferred embodiment of a processing chamber of the present invention.

FIG. 5 is a third preferred embodiment of a processing chamber of the present invention.

FIG. 6A is an elevation view showing a fourth preferred embodiment of a processing chamber of the present invention.

FIG. 6B is a lateral view showing a fourth preferred embodiment of a processing chamber of the present invention.

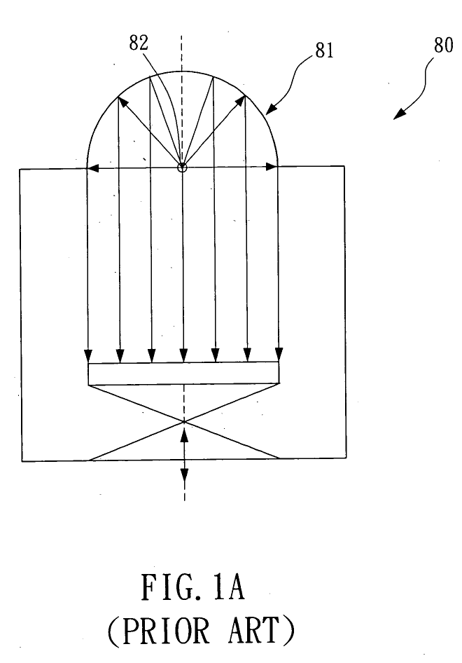

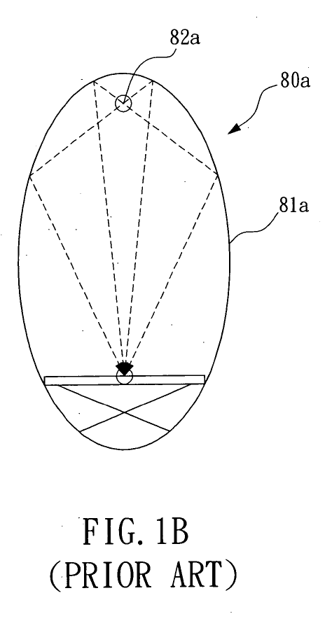

### DESCRIPTION OF THE PREFERRED EMBODIMENT

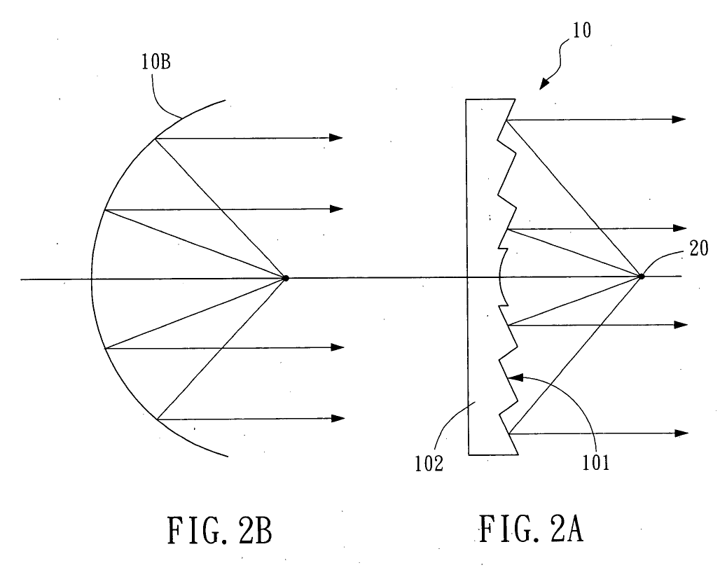

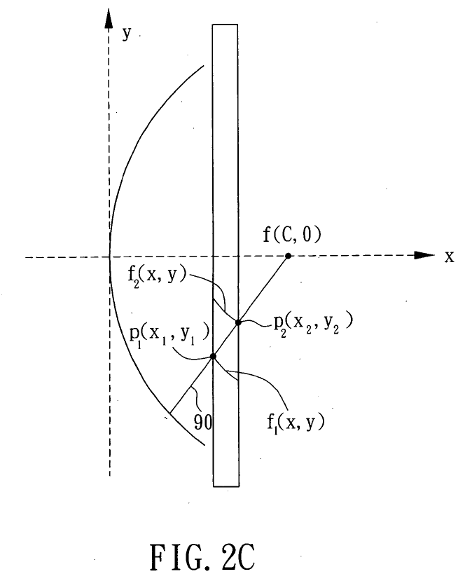

Referring to FIG. 2A, a lateral view of a curved spherical surface of a chamber in accordance with the present invention is shown. The curved spherical surface 10 of the present invention operates in coordination with an energy wave source 20 to project uniform energy wave toward a predetermined region. When the energy wave of the energy wave source 20 is projected to the curved spherical surface 10, the energy wave can be projected to the predetermined region in parallel by means of the curved spherical surface 10, and the curved spherical surface 10 can substitute a general reflector 10B with curved-surface structure (as shown in FIG. 2B) for the purpose of reducing the reflector's size and manufacture cost.

The curved spherical surface 10 may be composed of at least one kind of curved surface. The curved spherical surface 10 comprises: a curved reflecting surface 101 and a first top surface 102 spacing apart from one another at a specific distance for forming the curved spherical surface 10 with a specific thickness. The curved reflecting surface 101 surrounds the energy wave source 20 in a non-enclosure manner and spaces apart from the energy wave source 20 at a predetermined distance so as to reflect the energy wave emitted toward the curved reflecting surface 101. The curved reflecting surface 101 adopts the location of the energy wave source 20 as a focal point for defining the same, that is, defining a plurality of curves and selecting a portion of these curves to define the curved reflecting surface 101, while all of these curves adopt this focal point as their focal point. In the preferred embodiment of the present invention, the curved spherical surface 10 is illustrated with a single curved reflecting surface 101 for the purpose of explanation. It is apparent that the curved spherical surface 10 may be a single parabolic surface, a single hyperbolic surface, a single curved surface, or a combination of different curved surfaces. These above-mentioned shapes and variations of combination thereof, which are enveloped in the scope of the present invention, can be accomplished by a person skilled in the art in accordance with description of the present invention, wherein the redundant description about those are omitted herein. In theory, if a parabolic curve adopts a focal point F as its focal point, infinite parabolic curves can be obtained, wherein each of these parabolic curves satisfies the condition of adopting this focal point F as its focal point. Accordingly, assuming that a specific parabolic curve equation F (X, Y) satisfies the condition of adopting the focal point F as its focal point, which can be replaced by a Fresnel reflector having a specific thickness defined by selecting a reference point in specific space, and after specific calculation, forming several curves as the surfaces of the Fresnel reflector. Accordingly, it is noted that the curved spherical surface 101 can be a Fresnel reflector, a wave spherical surface with a portion thereof being replaced by a Fresnel reflector, a curved spherical surface with a portion therof being replaced by at least two Fresnel reflectors, and a surface entirely formed of a plurality of Fresnel reflectors. In other words, the curved spherical surface 10 of the present invention is accomplished by variations of above-mentioned combinations. As shown in FIG. 2C, which is illustrated for explaining the method for defining the plural curved surfaces of a Fresnel reflector as the reflector meaning is made up of many small segments rather than one continuous surface. It is assumed that a straight line 90 passes through the focal point f(C, 0) of a certain continuous surface and the straight line 90 intersects the reflector 10 with a specific thickness at two points, i.e. P1(x1, y1) and P2(x2, y2). Next, curve equations of f1(x, y) and f2(x, y) are obtained respectively with respect to f(C, 0) and P1(x1, y1), f(C, 0) and P2(x2, y2). BY virtue of this, a plurality of curved surfaces can be obtained by means of the aforementioned principle. Thereafter, a Fresnel reflector formed by a plurality of curved surfaces with focal point f(C. 0) is obtained.

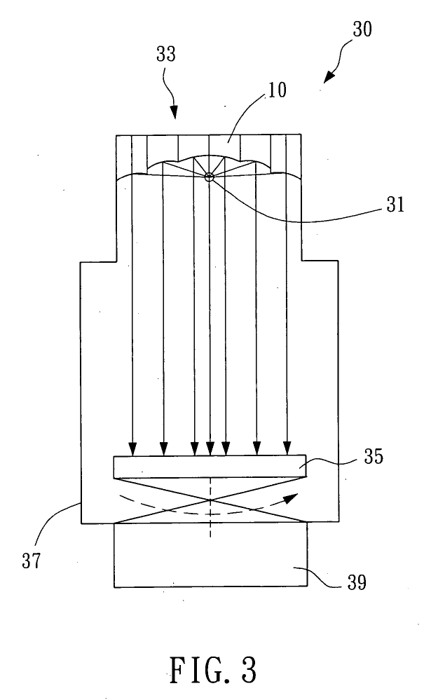

Referring to FIG. 3, a first preferred embodiment of a chamber device of the present invention is shown. The chamber device 30 at least comprises: an energy wave source 31, a chamber 33, a platform 35, and a base 37. The energy wave source 31 is a microwave source for supplying microwave. The microwave is transmitted from the energy wave source 31 to the inside of the chamber device 30 through a waveguide (not shown). Instead of the waveguide, the microwave may be transmitted to the inside of the chamber device 30 through an antenna (not shown). In this preferred embodiment, the microwave source is illustrated for exemplification, and the type of the energy wave source is not limited to the microwave source. It is allowable for user to select a desired type for the energy wave source. The chamber 33 surrounds the energy wave source 31 in a non-enclosure manner. A sealed space is formed between and by the chamber 33 and the base 37. The chamber 33 has a curved spherical surface 10 disposed at the upper portion of the chamber 33, wherein the numbering of the curved spherical surface 10 is designated as the same number as shown in FIG. 2A and the redundant description about it is omitted herein. Moreover, the energy wave source 31 is disposed on the focal point of the curved spherical surface 10 such that the energy wave of the energy wave source 31 is uniformly reflected to the platform 35 by the curved spherical surface 10. Furthermore, the platform 35 is further connected to a moving device 39 by which the platform 35 is allowed to perform three-dimensional movements and the moving direction of the platform 35 is set according to the requirement of the user thereby projecting the energy wave on the platform more uniformly. Besides, a reactor supplying device is mounted on the platform 35 for providing a reaction gas thereto, for example, hydrogen, methane, etc, for the platform 35, moreover, the reaction is performed by means of the energy.

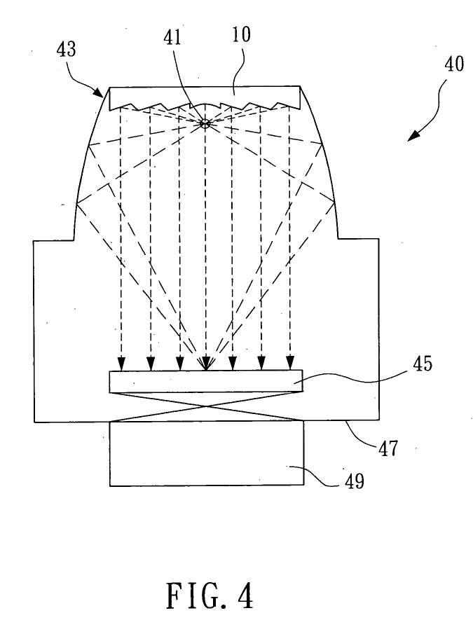

Referring to FIG. 4, a second preferred embodiment of a chamber device of the present invention is shown. The chamber device 40 comprises: an energy wave source 41, a chamber 43, a platform 45, and a base 47. The energy wave source 41 is a microwave source for supplying microwave. The microwave is transmitted from the energy wave source 41 to the inside of the chamber device 40 through a waveguide (not shown). Instead of the waveguide, the microwave may be transmitted to the inside of the chamber device 40 through an antenna (not shown). The chamber 43 surrounds the energy wave source 41 in a non-enclosure manner and a sealed space is formed between and by the chamber 43 and the base 47. A curved spherical surface 10 of the chamber is disposed above the chamber 43, wherein the curved spherical surface 10 is designated as the same number as shown in FIG. 2A and the redundant description about it is omitted herein. The chamber 43 has an elliptic spherical surface. Moreover, the energy wave source 41 is disposed on an equivalent focal point of the chamber 43 and a reference point on the platform 45 is adopted as another equivalent focal point of the elliptic spherical surface. Accordingly, the energy wave of the energy wave source 41 can be reflected on the platform 45 by means of the curved spherical surface 10. Moreover, when the energy wave of the energy wave source 41 is projected to chamber 43, it is focused to the platform 45 by means of the chamber 43 to raise usage efficiency of energy wave. Furthermore, the platform 45 is further connected to a moving device 49 by which the platform 45 is allowed to perform three-dimensional movement and the moving direction of the platform 45 is set according to the requirement of the user thereby projecting the energy wave on the platform uniformly. In this preferred embodiment, the chamber 43 is illustrated as an elliptic spherical surface, and the chamber may be an equivalent parabolic spherical surface, an equivalent hyperbolic spherical surface, or any other kind of curved spherical surface for a person skilled in the art. No matter what kind of spherical surface is applied, the energy wave source can be disposed a corresponding position as long as the equivalent focal point of the spherical surface is evaluated precisely. Since the energy wave source is disposed on the focal point, the reflected energy wave can be projected to the platform uniformly through performing appropriate three dimensional movement of platform for achieving the purpose of the present invention.

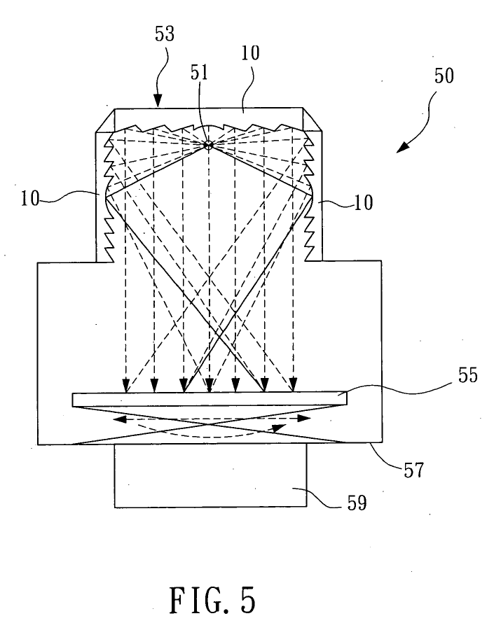

Referring to FIG. 5, a third preferred embodiment of the chamber device of the present invention is shown. The chamber device 50 comprises: an energy wave source 51, a chamber 53, a platform 55, and a base 57. The energy wave source 51 is a microwave source for supplying microwave. The microwave is transmitted from the energy wave source 51 to the inside of the chamber device 50 through a waveguide (not shown). Instead of the waveguide, the microwave may be transmitted to the inside of the chamber device 50 through an antenna (not shown). The chamber 53 surrounds the energy wave source 51 in a non-enclosure manner. Sealed space is formed between the chamber 53 and the base 57. A plurality of curved spherical surfaces 10 is disposed inside the chamber 53, wherein the curved spherical surface 10 is designated as the same number as shown in FIG. 2A and the redundant description about it is omitted herein. Moreover, the energy wave of the energy wave source 51 is reflected to the platform 55 by the curved spherical surface 10. Besides, the energy wave of the energy wave source 51 is also reflected to the platform 55 by the curved spherical surface 10 so as to improve the energy wave uniformity when the energy wave of the energy wave source 51 is projected to both sides of the chamber 53. Furthermore, the platform 55 is further connected to a moving device 59 by which the platform 55 is allowed to perform three-dimensional movement and the moving direction of the platform 55 is set according to the requirement of the user thereby projecting the energy wave on the platform uniformly.

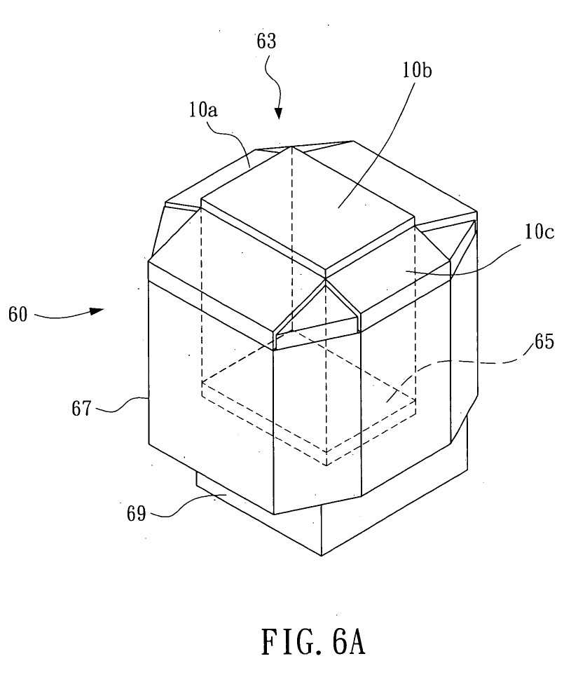

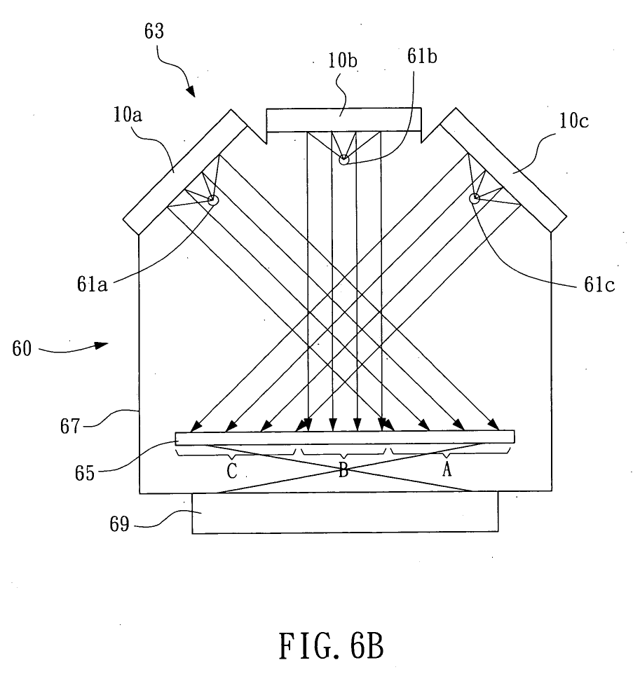

Referring to FIG. 6A and FIG. 6B, a fourth preferred embodiment of a chamber device of the present invention is shown. In comparison with the third preferred embodiment, the only difference between them in that the chamber of the fourth preferred embodiment comprises multiple energy wave sources inside thereof to provide at least two energy wave sources for supplying energy wave, and several curved spherical surfaces with a number corresponding to that of the multiple energy wave sources for reflecting the multiple energy wave sources and projecting the energy wave to the platform. Its operation theory has been completely disclosed in the above-mentioned preferred embodiments and the redundant description about that is omitted herein.

Referring to FIG. 6A and FIG. 6B, an elevation view and a lateral view of the fourth preferred embodiment of the chamber device of the present invention are shown respectively. The chamber device 60 comprises: multiple energy wave sources 61a, 61b, 61c for supplying energy wave (though three energy wave sources are illustrated in these figures, the number of the energy wave sources that can be set according to requirement of the user is not limited thereto), a chamber 63, a platform 65, and a base 67. In this preferred embodiment, the energy wave sources 61a, 61b, 61c are microwave sources. Nevertheless, they can be light sources or other well-known energy wave sources for a person skilled in the art. Sealed space is formed between the chamber 63 and the base 67. Several curved spherical surfaces 10a, 10b, 10c with a number corresponding to that of the multiple energy wave sources 61a, 61b, 61c are mounted inside the chamber 63 to reflect energy wave to the platform 65. Although three curved spherical surfaces are illustrated in these figures, the number of the curved spherical surfaces is not limited thereto and can be set according to requirement of the user. The curved spherical surfaces are the same as shown in FIG. 2A and the redundant description about it is omitted herein. In accordance with concept of modularization disclosed in this preferred embodiment, energy wave with large area can be supplied for the platform 65 for plating diamond film on large area. By mounting the curved spherical surfaces 10a, 10b, 10c above the platform 65, the energy wave sources 61a, 61b, 61c are disposed respectively on the focal points of the curved spherical surfaces 10a, 10b, 10c so as to reflect the energy wave of energy wave source 61a, 61b, 61c to a first specific region A, a second specific region B, and a third specific region C of the platform 65 by means of the curved spherical surface 10a, the curved spherical surface 10b, and the curved spherical surface 10c respectively. By use of such arrangement, the energy wave source with large area can be provided for projecting the energy wave of the energy wave source to the platform.

In this preferred embodiment, the energy wave source 61a, 61b, 61c are disposed on the equivalent focal points, and the detailed description about their positions has been described above and is therefore omitted herein. Even though the number of the energy wave source 61a, 61b, 61c and the number of the curved spherical surfaces 10a, 10b, 10c are three respectively, they can be increased for increasing the area of the energy wave source in accordance with the desired area of the user. Accordingly, the user is provided with ability to dispose the energy wave source and the reflector for achieving the purpose of modularization flexibly.

Moreover, the platform 65 is further connected to a moving device 69 by which the platform 65 is allowed to perform three-dimensional movement (for example, rotation, straight oscillation and other well-known movement for a person skilled in the art) and the moving direction of the platform 65 is set according to the requirement of the user thereby projecting the energy wave on the platform 65 uniformly.

It is capable of plating the diamond film on a large area substrate by use of the above-mentioned chamber device 60. The substrate is disposed on the platform 65 and the large area energy wave is projected on the substrate by means of the energy wave sources 61a, 61b, 61c and the curved spherical surfaces 10a, 10b, 10c for supplying the energy wave uniformly for every region of the substrate to develop the diamond film. Moreover, the moving device 69 is further provided for moving the platform 65 so as to project the energy wave on the substrate uniformly.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What is claimed is:

1. A process chamber with wave reflectors, comprising:
an energy wave source, for supplying an energy wave; and
a curved spherical surface, consisting of at least a Fresnel reflector for reflecting the energy wave and projecting the same onto a platform.

2. The process chamber with wave reflectors of claim 1, wherein the energy wave source is selected from the group consisting of a microwave source, a light source and the likes.

3. The process chamber with wave reflectors of claim 1, wherein the curved spherical surface is selected from the group consisting of a Fresnel reflector, a curved spherical surface with a portion thereof being replaced by a Fresnel reflector, a curved spherical surface with a portion thereof being replaced by at least two Fresnel reflectors, and a surface entirely formed of a plurality of Fresnel reflectors.

4. The process chamber with wave reflectors of claim 1, wherein the curved spherical surface is equivalent to a parabolic spherical surface.

5. The process chamber with wave reflectors of claim 4, wherein the energy wave source is disposed on an equivalent focal point of the parabolic spherical surface enabling the energy wave discharged therefrom to be reflected by the curved spherical surface and thus projected onto the platform uniformly.

6. The process chamber with wave reflectors of claim 1, wherein the curved spherical surface is equivalent to an elliptic spherical surface.

7. The process chamber with wave reflectors of claim 6, wherein the energy wave source is disposed on an equivalent focal point of the elliptic spherical surface enabling the energy wave discharged therefrom to be reflected and focused to another equivalent focal point of the elliptic spherical surface.

8. The process chamber with wave reflectors of claim 1, wherein the platform is further connected to a moving device to allow the platform to perform a three-dimensional movement.

9. The process chamber with wave reflectors of claim 1, wherein the curved spherical surface is composed of at least one kind of curved surface.

10. A process chamber with wave reflectors, comprising:
at least two energy wave sources, for supplying energy waves; and
at least two curved spherical surface, each reflecting the energy wave discharged from a corresponding energy wave source and projecting the same onto a platform.

11. The process chamber with wave reflectors of claim 10, wherein the energy wave source is selected from the group consisting of a microwave source, a light source and the likes.

12. The process chamber with wave reflectors of claim 10, wherein each curved spherical surface is selected from the group consisting of a Fresnel reflector, a curved spherical surface with a portion thereof being replaced by a Fresnel reflector, a curved spherical surface with a portion thereof being replaced by at least two Fresnel reflector, and a surface entirely formed of a plurality of Fresnel reflectors.

13. The process chamber with wave reflectors of claim 10, wherein the curved spherical surface is equivalent to a parabolic spherical surface.

14. The process chamber with wave reflectors of claim 13, wherein each energy wave source is disposed respectively on a first equivalent focal point of the corresponding curved spherical surface enabling the energy wave discharged therefrom to be reflected by the corresponding curved spherical surface and thus projected onto the platform.

15. The process chamber with wave reflectors of claim 14, wherein the plural reflected energy waves are projected onto the platform at positions selected from the group consisting of: a plurality of areas of the platform in respective, and an identical area of the platform simultaneously.

16. The process chamber with wave reflectors of claim 10, wherein the curved spherical surface is equivalent to an elliptic spherical surface.

17. The process chamber with wave reflectors of claim 16, wherein each energy wave source is disposed respectively on a second equivalent focal point of the corresponding curved spherical surface enabling the energy wave discharged therefrom to be reflected and focused to another equivalent focal point of the elliptic spherical surface.

18. The process chamber with wave reflectors of claim 17, wherein the elliptic spherical surfaces have a common second focal point for focusing the corresponding reflected energy waves thereat so as to increase energy density of a projection region.

19. The process chamber with wave reflectors of claim 17, wherein the elliptic spherical surfaces have different second focal points for enabling the processing chamber to have a plurality of high-energy regions.

20. The process chamber with wave reflectors of claim 10, wherein the platform is further connected to a moving device to allow the platform to perform a three-dimensional movement.

21. The process chamber with wave reflectors of claim 10, wherein the curved spherical surface is composed of at least one kind of curved spherical surface.
